(19) United States
(12) Patent Application Publication
(10) Pub. No.: US 2014/0144771 A1
(43) Pub. Date: May 29, 2014

(54) Cooling Efficiency Method for Fluid Cooled Sputter Guns

(71) Applicant: INTERMOLECULAR, INC., San Jose, CA (US)

(72) Inventors: Kent Riley Child, Dublin, CA (US); Hong Sheng Yang, Pleasanton, CA (US)

(73) Assignee: INTERMOLECULAR, INC., San Jose, CA (US)

(21) Appl. No.: 13/687,984

(22) Filed: Nov. 28, 2012

(51) Int. Cl. C23C 14/35

(52) U.S. Cl. CPC C23C 14/35
USPC 204/192.12; 204/298.09

(57) ABSTRACT

A sputter gun assembly is provided. The sputter gun assembly includes a target and a target backing plate coupled to the back of the target. A magnetron is positioned within a cooling chamber and is disposed over the target backing plate and defines a gap between the magnetron and the target backing plate. A fluid inlet and a fluid outlet are connected to the cooling chamber. A restriction bar is positioned within the cooling chamber, wherein the restriction bar is configured to prevent a flow of fluid through the inlet to the outlet unless the fluid traverses the gap defined between the magnetron and the target backing plate. The sputter gun assembly further includes a diverter surrounding the magnetron. The diverter further includes slots in its surface that serve to direct cooling fluid through the gap formed between defined between the magnetron and the target backing plate.

### TECHNICAL FIELD

The present disclosure relates generally to methods and apparatus for improved cooling of fluid cooled sputter guns.

### BACKGROUND

Physical vapor deposition (PVD) is commonly used within the semiconductor industry as well as within solar, glass coating, and other industries, in order to deposit a layer over a substrate. Sputtering is a common physical vapor deposition method, where atoms or molecules are ejected from a target material by high-energy particle bombardment and then deposited onto the substrate.

In order to identify different materials, evaluate different unit process conditions or parameters, or evaluate different sequencing and integration of processes, and combinations thereof, it may be desirable to be able to process different regions of the substrate differently. This capability, hereinafter called “combinatorial processing”, is generally not available with tools that are designed specifically for conventional full substrate processing. Furthermore, it may be desirable to subject localized regions of the substrate to different processing conditions (e.g., localized deposition) in one step of a sequence followed by subjecting the full substrate to a similar processing condition (e.g., full substrate deposition) in another step.

Current full-substrate PVD tools used in the semiconductor industry have a large sputtering source including a large sputtering target, i.e., the target is larger than the substrate in order to deposit a uniform layer on the substrate, even for substrates as large as 300 mm wafer. Alternatively, some full substrate PVD tools use a smaller sputtering source, e.g., 3″ or 4″ diameter target, and rotate the wafer in order to deposit a uniform film, where the substrate may be 200 mm diameter or smaller, and the sputtering source is pointed to approximately the mid-radius of the substrate. In these methods, the target-to-substrate spacing is relatively large, e.g., 200 mm, requiring significant space between the sputtering source and the substrate in order to deposit a uniform film on the full substrate.

Combinatorial processing chambers typically include smaller sputtering sources. However, deposition rates can suffer. A plurality of small sputtering sources aimed at a common location on a substrate must be positioned at a significant distance from the substrate to ensure good uniformity of the deposited film within an isolated spot. Particularly for thick film applications such as the formation of metal and metal nitride electrodes, process times of several hours are common. Significant contamination and poor film quality are common byproducts of long processing time.

### SUMMARY

The following summary of the disclosure is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

In some embodiments, a sputter gun assembly is provided. The sputter gun assembly includes a target and a target backing plate coupled to the back of the target (e.g. the surface that is not sputtered). A magnetron is positioned within a cooling chamber and is disposed over the target backing plate and defines a gap between the magnetron and the target backing plate. A fluid inlet and a fluid outlet are connected to the cooling chamber. A restriction bar is positioned within the cooling chamber, wherein the restriction bar is configured to prevent a flow of fluid through the inlet to the outlet unless the fluid traverses the gap defined between the magnetron and the target backing plate. The sputter gun assembly further includes a diverter surrounding the magnetron. The diverter further includes slots in its surface that serve to direct cooling fluid through the gap formed between defined between the magnetron and the target backing plate.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 illustrates a schematic diagram for implementing combinatorial processing and evaluation using primary, secondary, and tertiary screening.

FIG. 2 is a simplified schematic diagram illustrating a general methodology for combinatorial process sequence integration.

FIG. 3 is a simplified schematic diagram illustrating an integrated high productivity combinatorial (HPC) system in accordance with some embodiments of the invention.

FIG. 4 is a simplified schematic diagram illustrating a sputter chamber configured to perform combinatorial processing and full substrate processing in accordance with some embodiments of the invention.

FIGS. 5A and 5B are simplified schematic diagrams illustrating a sputter gun according to some embodiments.

FIGS. 6A and 6B are simplified schematic diagrams illustrating a sputter gun according to some embodiments.

FIGS. 7A-7C are simplified schematic diagrams illustrating a sputter gun according to some embodiments.

FIG. 8 presents data for temperature versus cooling water flow rate according to some embodiments.

FIG. 9 presents data for temperature versus cooling water flow rate according to some embodiments.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

Semiconductor manufacturing typically includes a series of processing steps such as cleaning, surface preparation, deposition, patterning, etching, thermal annealing, and other related unit processing steps. The precise sequencing and integration of the unit processing steps enables the formation of functional devices meeting desired performance metrics such as efficiency, power production, and reliability.

As part of the discovery, optimization and qualification of each unit process, it is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices such as integrated circuits. In particular, there is a need to be able to test i) more than one material, ii) more than one processing condition, iii) more than one sequence of processing conditions, iv) more than one process sequence integration flow, and combinations thereof, collectively known as “combinatorial process sequence integration”, on a single monolithic substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009 which are all herein incorporated by reference. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005 which are all herein incorporated by reference.

HPC processing techniques have been successfully adapted to wet chemical processing such as etching and cleaning. HPC processing techniques have also been successfully adapted to deposition processes such as physical vapor deposition (PVD), atomic layer deposition (ALD), and chemical vapor deposition (CVD).

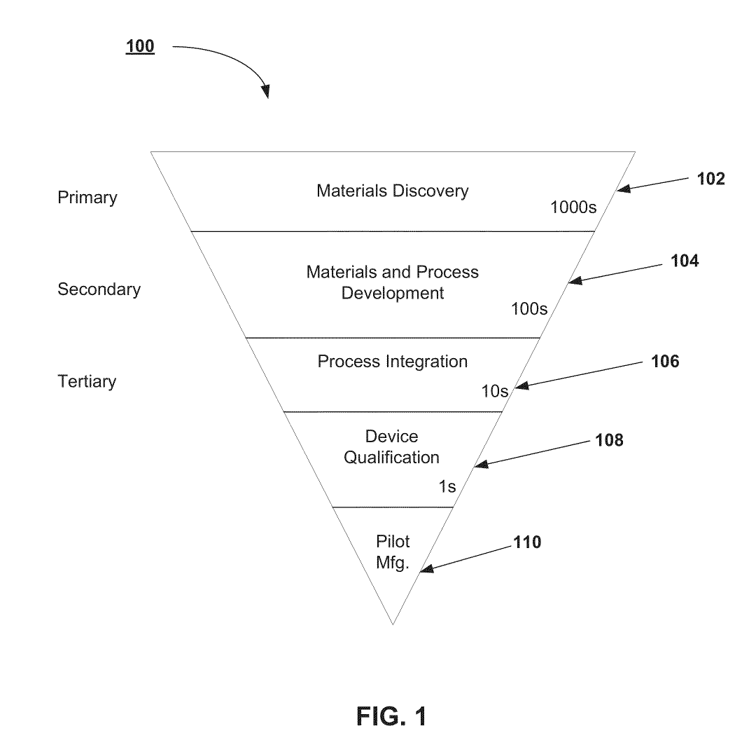

FIG. 1 illustrates a schematic diagram, 100, for implementing combinatorial processing and evaluation using primary, secondary, and tertiary screening. The schematic diagram, 100, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage, 102. Materials discovery stage, 102, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e., microscopes).

The materials and process development stage, 104, may evaluate hundreds of materials (i.e., a magnitude smaller than the primary stage) and may focus on the processes used to deposit or develop those materials. Promising materials and processes are again selected, and advanced to the tertiary screen or process integration stage, 106, where tens of materials and/or processes and combinations are evaluated. The tertiary screen or process integration stage, 106, may focus on integrating the selected processes and materials with other processes and materials.

The most promising materials and processes from the tertiary screen are advanced to device qualification, 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 110.

The schematic diagram, 100, is an example of various techniques that may be used to evaluate and select materials and processes for the development of new materials and processes. The descriptions of primary, secondary, etc. screening and the various stages, 102-110, are arbitrary and the stages may overlap, occur out of sequence, be described and be performed in many other ways.

This application benefits from High Productivity Combinatorial (HPC) techniques described in U.S. patent application Ser. No. 11/674,137 filed on Feb. 12, 2007 which is hereby incorporated for reference in its entirety. Portions of the '137 application have been reproduced below to enhance the understanding of the present invention. The embodiments described herein enable the application of combinatorial techniques to process sequence integration in order to arrive at a globally optimal sequence of semiconductor manufacturing operations by considering interaction effects between the unit manufacturing operations, the process conditions used to effect such unit manufacturing operations, hardware details used during the processing, as well as materials characteristics of components utilized within the unit manufacturing operations. Rather than only considering a series of local optimums, i.e., where the best conditions and materials for each manufacturing unit operation is considered in isolation, the embodiments described below consider interactions effects introduced due to the multitude of processing operations that are performed and the order in which such multitude of processing operations are performed when fabricating a device. A global optimum sequence order is therefore derived and as part of this derivation, the unit processes, unit process parameters and materials used in the unit process operations of the optimum sequence order are also considered.

The embodiments described further analyze a portion or sub-set of the overall process sequence used to manufacture a semiconductor device. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate that are equivalent to the structures formed during actual production of the semiconductor device. For example, such structures may include, but would not be limited to, contact layers, buffer layers, absorber layers, or any other series of layers or unit processes that create an intermediate structure found on semiconductor devices. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each region are designed to enable valid statistical analysis of the test results within each region and across regions to be performed.

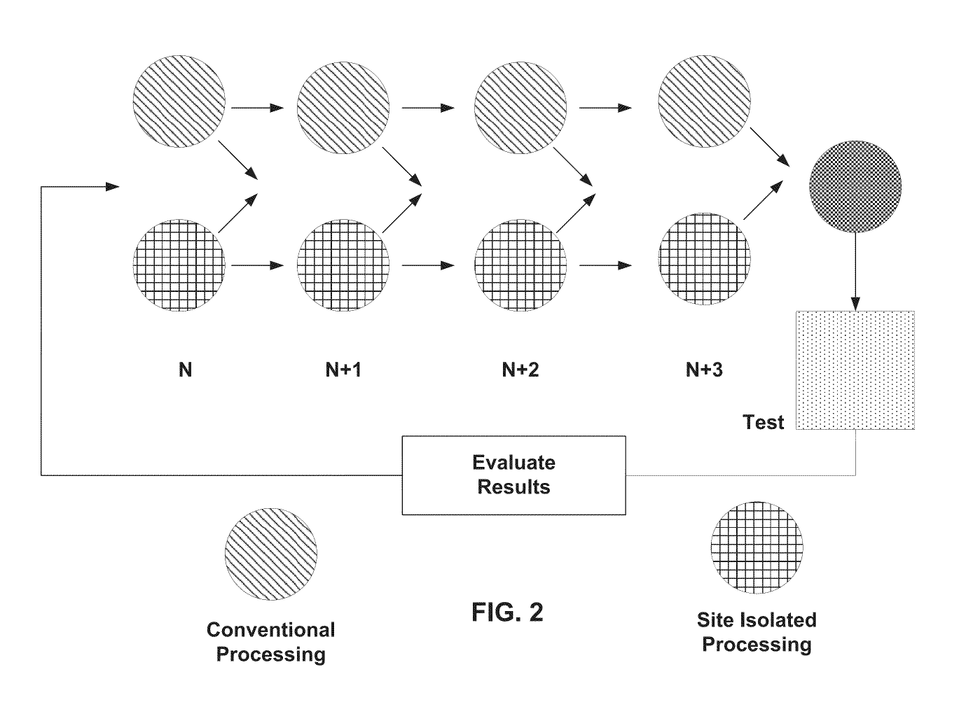

FIG. 2 is a simplified schematic diagram illustrating a general methodology for combinatorial process sequence integration that includes site isolated processing and/or conventional processing in accordance with one embodiment of the invention. In one embodiment, the substrate is initially processed using conventional process N. In one exemplary embodiment, the substrate is then processed using site isolated process N+1. During site isolated processing, an HPC module may be used, such as the HPC module described in U.S. patent application Ser. No. 11/352,077 filed on Feb. 10, 2006. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in semiconductor manufacturing may be varied.

As mentioned above, within a region, the process conditions are substantially uniform, in contrast to gradient processing techniques which rely on the inherent non-uniformity of the material deposition. That is, the embodiments, described herein locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. It should be appreciated that a region may be adjacent to another region in one embodiment or the regions may be isolated and, therefore, non-overlapping. When the regions are adjacent, there may be a slight overlap wherein the materials or precise process interactions are not known, however, a portion of the regions, normally at least 50% or more of the area, is uniform and all testing occurs within that region. Further, the potential overlap is only allowed with material of processes that will not adversely affect the result of the tests. Both types of regions are referred to herein as regions or discrete regions.

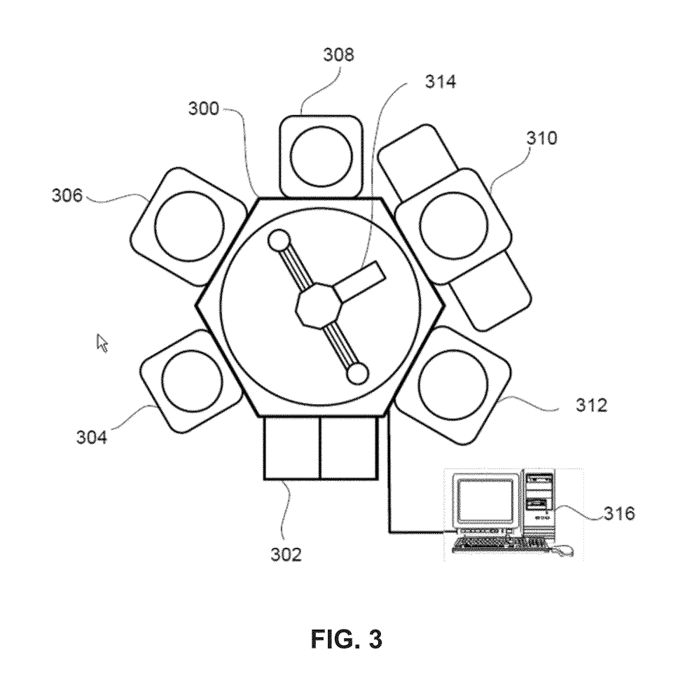

FIG. 3 is a simplified schematic diagram illustrating an integrated high productivity combinatorial (HPC) system in accordance with some embodiments of the invention. HPC system includes a frame 300 supporting a plurality of processing modules. It should be appreciated that frame 300 may be a unitary frame in accordance with some embodiments. In some embodiments, the environment within frame 300 is controlled. Load lock/factory interface 302 provides access into the plurality of modules of the HPC system. Robot 314 provides for the movement of substrates (and masks) between the modules and for the movement into and out of the load lock 302. Modules 304-312 may be any set of modules and preferably include one or more combinatorial modules. For example, module 304 may be an orientation/degassing module, module 306 may be a clean module, either plasma or non-plasma based, modules 308 and/or 310 may be combinatorial/conventional dual purpose modules. Module 312 may provide conventional clean or degas as necessary for the experiment design.

Any type of chamber or combination of chambers may be implemented and the description herein is merely illustrative of one possible combination and not meant to limit the potential chamber or processes that can be supported to combine combinatorial processing or combinatorial plus conventional processing of a substrate or wafer. In some embodiments, a centralized controller, i.e., computing device 316, may control the processes of the HPC system, including the power supplies and synchronization of the duty cycles described in more detail below. Further details of one possible HPC system are described in U.S. application Ser. Nos. 11/672,478 and 11/672,473. With HPC system, a plurality of methods may be employed to deposit material upon a substrate employing combinatorial processes.

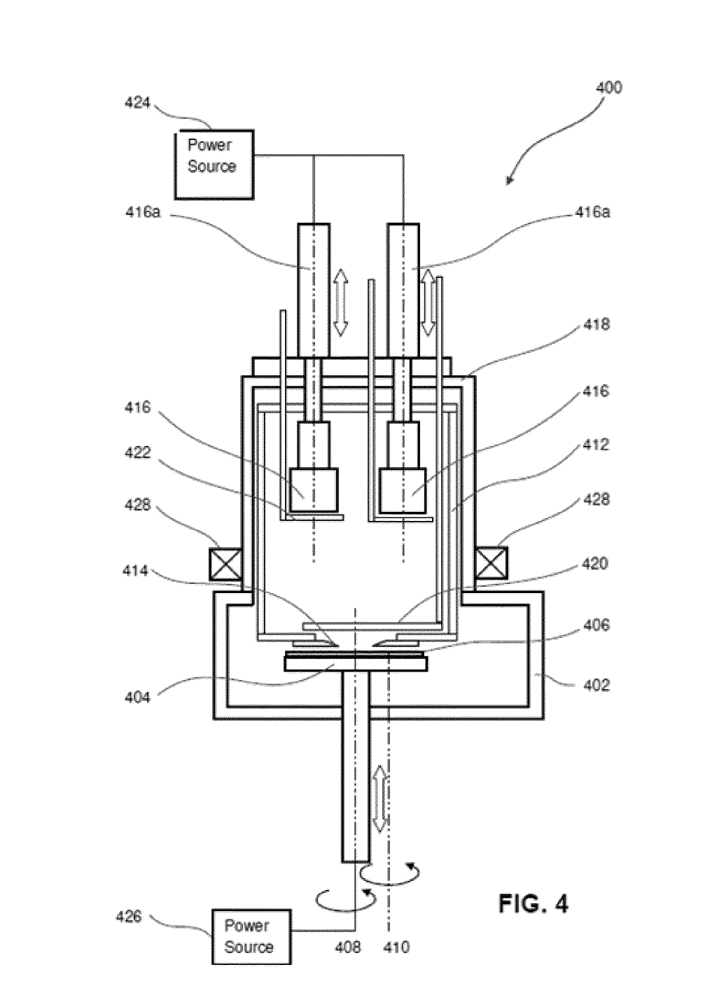

FIG. 4 is a simplified schematic diagram illustrating a sputter chamber configured to perform combinatorial processing and full substrate processing in accordance with some embodiments of the invention. Processing chamber 400 includes a bottom chamber portion 402 disposed under top chamber portion 418. Within bottom portion 402, substrate support 404 is configured to hold a substrate 406 disposed thereon and can be any known substrate support, including but not limited to a vacuum chuck, electrostatic chuck or other known mechanisms. Substrate support 404 is capable of both rotating around its own central axis 408 (referred to as “rotation” axis), and rotating around an exterior axis 410 (referred to as “revolution” axis). Such dual rotary substrate support is central to combinatorial processing using site-isolated mechanisms. Other substrate supports, such as an XY table, can also be used for site-isolated deposition. In addition, substrate support 404 may move in a vertical direction. It should be appreciated that the rotation and movement in the vertical direction may be achieved through known drive mechanisms which include magnetic drives, linear drives, worm screws, lead screws, a differentially pumped rotary feed through drive, etc. Power source 426 provides a bias power to substrate support 404 and substrate 406, and produces a negative bias voltage on substrate 406. In some embodiments power source 426 provides a radio frequency (RF) power sufficient to take advantage of the high metal ionization to improve step coverage of vias and trenches of patterned wafers. In another embodiment, the RF power supplied by power source 426 is pulsed and synchronized with the pulsed power from power source 424. Further details of the power sources and their operation may be found in U.S. patent application Ser. No. 13/281,316 entitled “High Metal Ionization Sputter Gun” filed on Oct. 25, 2011 and is herein incorporated by reference for all purposes.

Substrate 406 may be a conventional round 200 mm, 300 mm, or any other larger or smaller substrate/wafer size. In some embodiments, substrate 406 may be a square, rectangular, or other shaped substrate. One skilled in the art will appreciate that substrate 406 may be a blanket substrate, a coupon (e.g., partial wafer), or even a patterned substrate having predefined regions. In another embodiment, substrate 406 may have regions defined through the processing described herein. The term region is used herein to refer to a localized area on a substrate which is, was, or is intended to be used for processing or formation of a selected material. The region can include one region and/or a series of regular or periodic regions predefined on the substrate. The region may have any convenient shape, e.g., circular, rectangular, elliptical, wedge-shaped, etc. In the semiconductor field a region may be, for example, a test structure, single die, multiple dies, portion of a die, other defined portion of substrate, or an undefined area of a substrate, e.g., blanket substrate which is defined through the processing.

Top chamber portion 418 of chamber 400 in FIG. 4 includes process kit shield 412, which defines a confinement region over a radial portion of substrate 406. Process kit shield 412 is a sleeve having a base (optionally integrated with the shield) and an optional top within chamber 400 that may be used to confine a plasma generated therein. The generated plasma will dislodge atoms from a target and the sputtered atoms will deposit on an exposed surface of substrate 406 to combinatorial process regions of the substrate in some embodiments. In another embodiment, full wafer processing can be achieved by optimizing gun tilt angle and target-to-substrate spacing, and by using multiple process guns 416. Process kit shield 412 is capable of being moved in and out of chamber 400, i.e., the process kit shield is a replaceable insert. In another embodiment, process kit shield 412 remains in the chamber for both the full substrate and combinatorial processing. Process kit shield 412 includes an optional top portion, sidewalls and a base. In some embodiments, process kit shield 412 is configured in a cylindrical shape, however, the process kit shield may be any suitable shape and is not limited to a cylindrical shape.

The base of process kit shield 412 includes an aperture 414 through which a surface of substrate 406 is exposed for deposition or some other suitable semiconductor processing operations. Aperture shutter 420 which is moveably disposed over the base of process kit shield 412. Aperture shutter 420 may slide across a bottom surface of the base of process kit shield 412 in order to cover or expose aperture 414 in some embodiments. In another embodiment, aperture shutter 420 is controlled through an arm extension which moves the aperture shutter to expose or cover aperture 414. It should be noted that although a single aperture is illustrated, multiple apertures may be included. Each aperture may be associated with a dedicated aperture shutter or an aperture shutter can be configured to cover more than one aperture simultaneously or separately. Alternatively, aperture 414 may be a larger opening and plate 420 may extend with that opening to either completely cover the aperture or place one or more fixed apertures within that opening for processing the defined regions. The dual rotary substrate support 404 is central to the site-isolated mechanism, and allows any location of the substrate or wafer to be placed under the aperture 414. Hence, the site-isolated deposition is possible at any location on the wafer/substrate.

A gun shutter, 422 may be included. Gun shutter 422 functions to seal off a deposition gun when the deposition gun may not be used for the processing in some embodiments. For example, two process guns 416 are illustrated in FIG. 4. Process guns 416 are moveable in a vertical direction so that one or both of the guns may be lifted from the slots of the shield. While two process guns are illustrated, any number of process guns may be included, e.g., one, three, four or more process guns may be included. Where more than one process gun is included, the plurality of process guns may be referred to as a cluster of process guns. Gun shutter 422 can be transitioned to isolate the lifted process guns from the processing area defined within process kit shield 412. In this manner, the process guns are isolated from certain processes when desired. It should be appreciated that slide cover plate 422 may be integrated with the top of the process kit shield 412 to cover the opening as the process gun is lifted or individual cover plate 422 can be used for each target. In some embodiments, process guns 416 are oriented or angled so that a normal reference line extending from a planar surface of the target of the process gun is directed toward an outer periphery of the substrate in order to achieve good uniformity for full substrate deposition film. The target/gun tilt angle depends on the target size, target-to-substrate spacing, target material, process power/pressure, etc.

Top chamber portion 418 of chamber 400 of FIG. 4 includes sidewalls and a top plate which house process kit shield 412. Arm extensions 416a, which are fixed to process guns 416 may be attached to a suitable drive, e.g., lead screw, worm gear, etc., configured to vertically move process guns 416 toward or away from a top plate of top chamber portion 418. Arm extensions 416a may be pivotally affixed to process guns 416 to enable the process guns to tilt relative to a vertical axis. In some embodiments, process guns 416 tilt toward aperture 414 when performing combinatorial processing and tilt toward a periphery of the substrate being processed when performing full substrate processing. It should be appreciated that process guns 416 may tilt away from aperture 414 when performing combinatorial processing in another embodiment. In yet another embodiment, arm extensions 416a are attached to a bellows that allows for the vertical movement and tilting of process guns 416. Arm extensions 416a enable movement with four degrees of freedom in some embodiments. Where process kit shield 412 is utilized, the aperture openings are configured to accommodate the tilting of the process guns. The amount of tilting of the process guns may be dependent on the process being performed in some embodiments. Power source 424 provides power for sputter guns 416 whereas power source 426 provides RF bias power to an electrostatic chuck to bias the substrate when necessary. It should be appreciated that power source 424 may output a direct current (DC) power supply or a radio frequency (RF) power supply.

Chamber 400 includes auxiliary magnet 428 disposed around an external periphery of the chamber. The auxiliary magnet 428 is located in a region defined between the bottom surface of sputter guns 416 and a top surface of substrate 406. Magnet 428 may be either a permanent magnet or an electromagnet. It should be appreciated that magnet 428 is utilized to provide more uniform bombardment of argon ions and electrons to the substrate in some embodiments.

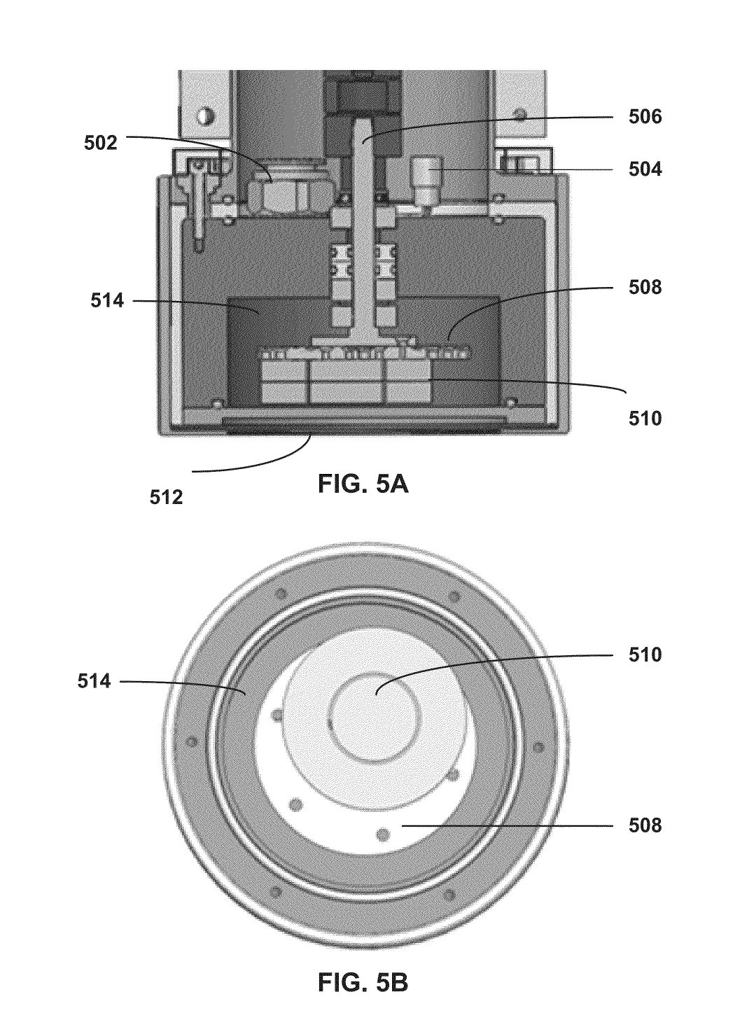

FIGS. 5A and 5B are simplified schematic diagrams illustrating a sputter gun according to some embodiments. FIG. 5A represents a simple cross-sectional view through a sputter gun assembly. The sputter gun assembly may be used in the HPC chamber and system described previously, or may be used in a convention chamber and system. The sputter gun assembly includes a target, 512, affixed to a backing plate. A magnetron (e.g magnet assembly), 510, is mounted to a universal shunt plate, 508, and is positioned proximate to the surface of the backing plate opposite the target. The spacing between the magnetron and the backing plate is typically about 0.5 mm. However, the spacing between the magnetron and the backing plate is adjustable. The universal shunt plate includes a grid of mounting holes that allows for rapid development and testing of magnet assemblies to improve the deposition characteristics of the sputter gun. The universal shunt plate is further described in U.S. patent application Ser. No. ______ filed on Nov. ______, 2012, and having internal Attorney Docket No. IM0410_US, which is herein incorporated by reference for all purposes. The shunt plate and magnetron may stationary or may be rotated using shaft, 506. The sputter gun assembly includes cooling chamber, 514, with fluid inlet, 502, and fluid outlet, 504. Typically, the cooling fluid includes water.

FIG. 5B represents a simple bottom view of the sputter gun assembly illustrated in FIG. 5A with the target and backing plate removed. In FIG. 5B, the shunt plate, 508, the magnetron, 510, and the cooling chamber, 514, are illustrated.

It is desirable to deposit materials with a high deposition rate to increase the throughput and lower the cost of ownership of the deposition step within the manufacture of the device. This desire is met by applying high powers to the sputter gun assembly. One consequence of the high power is the high temperatures that can be created within the target and backing plate. If the temperatures are not well managed, issues such as grain growth, target warpage, target melting, and the like can occur.

The cooling chamber, 514, illustrated in FIGS. 5A and 5B includes simple fluid paths. The cooling fluid will take the path of least resistance traversing from the fluid inlet, 502, to the fluid outlet, 504. Due to the small gap between the magnetron and the backing plate (typically about 0.5 mm, but adjustable), very little of the cooling fluid flows between the magnetron and the backing plate. Therefore, the cooling of the target is inefficient.

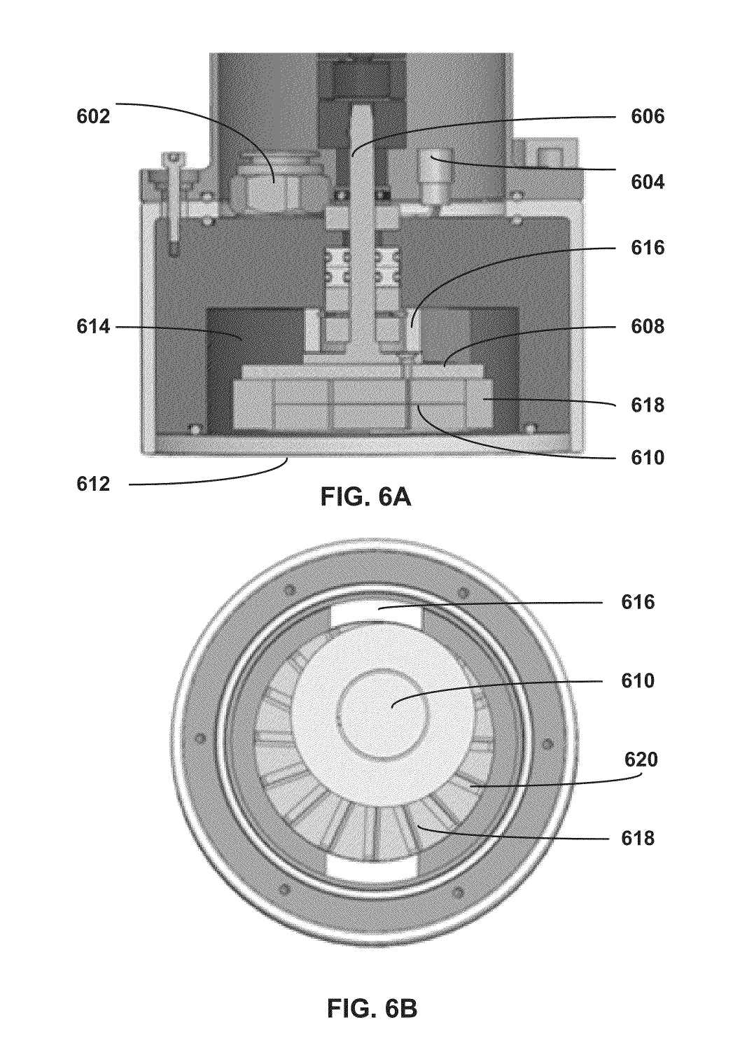

FIGS. 6A and 6B are simplified schematic diagrams illustrating a sputter gun according to some embodiments. FIG. 6A represents a simple cross-sectional view through a sputter gun assembly. The sputter gun assembly may be used in the HPC chamber and system described previously, or may be used in a convention chamber and system. The sputter gun assembly includes a target, 612, affixed to a backing plate. A magnetron (e.g. magnet assembly), 610, is mounted to a universal shunt plate, 608, and is positioned proximate to the surface of the backing plate opposite the target. The spacing between the magnetron and the backing plate is typically about 0.5 mm. However, the spacing between the magnetron and the backing plate is adjustable. The shunt plate and magnetron may stationary or may be rotated using shaft, 606. The sputter gun assembly includes cooling chamber, 614, with fluid inlet, 602, and fluid outlet, 604. Typically, the cooling fluid includes water. The sputter gun assembly further includes a flow restriction bar, 616, and a fluid diverter, 618.

FIG. 6B represents a simple bottom view of the sputter gun assembly illustrated in FIG. 6A with the target and backing plate removed. In FIG. 6B, the shunt plate, 608, the magnetron, 610, the cooling chamber, 614, flow restriction bar, 616, and fluid diverter, 618, are illustrated. Fluid diverter, 618, further includes slots, 620. The slots in the fluid diverter are positioned such that they are proximate to the target backing plate. The flow restriction bar, 616, is operable to prevent fluid from traversing from the fluid inlet, 602, to the fluid outlet, 604, unless the fluid traverses through the gap between the magnetron and the target backing plate. The fluid diverter, 618, and associated slots, 620, serve to force the fluid between the magnetron and the target backing plate as the magnetron is rotated.

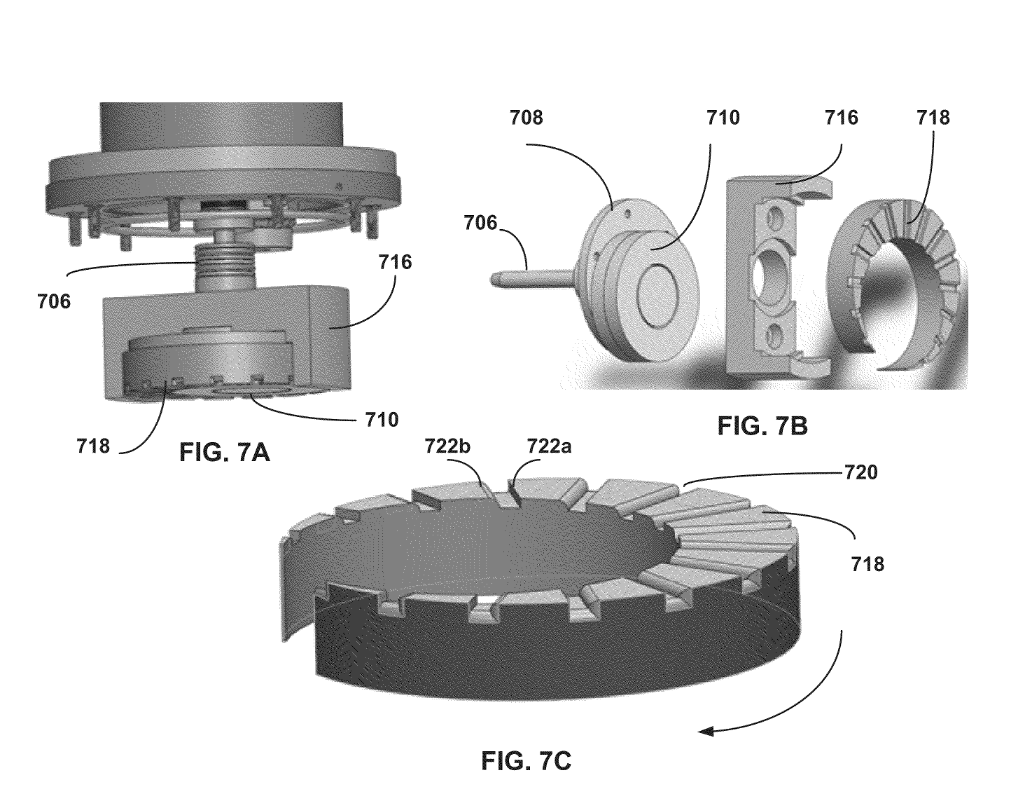

FIGS. 7A-7C are simplified schematic diagrams illustrating a sputter gun according to some embodiments. FIG. 7A represents a simple schematic illustrating the shaft, 706, flow restriction bar, 716, fluid diverter, 718, and magnetron, 710. In some embodiments, shaft, 706, can be moved in a vertical direction (i.e. perpendicular to the target surface) to adjust the gap between the magnetron and the target backing plate. In some embodiments, the magnetron, 710, and the fluid diverter, 718, rotate and the flow restriction bar, 716, remains stationary. The diverter is designed to fill the volume between the magnetron, 710, and the flow restriction bar, 716. As the magnetron, 710, and the fluid diverter, 718, are rotated, the cooling fluid must flow through the slots, 720, and will be forced through the gap between the magnetron and the target backing plate.

FIG. 7B represents a simple schematic illustrating the shaft, 706, shunt plate, 708, magnetron, 710, flow restriction bar, 716, and fluid diverter, 718. FIG. 7C represents a simple schematic illustrating the fluid diverter, 718, with slots, 720. As the fluid diverter rotates, the slots serve to force the fluid between the magnetron and the target backing plate. Each slot has a sharp edge, 722a, and a beveled edge, 722b. In some embodiments, the fluid diverter is rotated as indicated and the beveled edge acts like an airfoil to more efficiently force fluid through the slot. However, the design of the fluid diverter has been shown to improve the cooling when rotated in either direction.

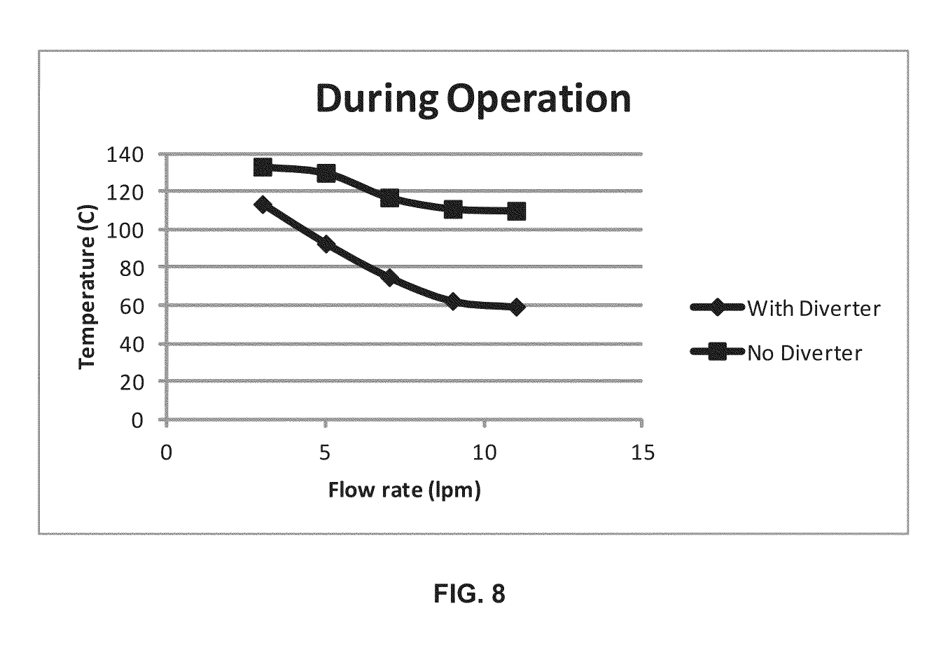

FIG. 8 presents data for temperature versus cooling water flow rate according to some embodiments. The magnetron and the fluid diverter were rotated at about 60 rpm. To simulate the target heating, a map gas torch was held at a distance of 2 inches from the target surface. The temperature of the map gas torch was about 2500C. The torch was allowed to heat the target surface for a period of 60 seconds and the temperature of the interface of the target to backing plate was measured with a thermocouple (TC) attached to the interface at the end of the 60 seconds. This configuration mimics the heating of the sputter gun assembly during the operation of the sputter gun. Cooling fluid (i.e. water) with a flow rate between 3 liter per minute (lpm) and 11 lpm was passed through the sputter gun assembly. The temperature was measured again, 30 seconds after the map gas torch was turned off. FIG. 8 presents the data for the temperature of the interface of the target to backing plate at the end of the 60 second heating period by the torch as a function of cooling fluid flow rate. The data labeled “No Diverter” and being illustrated with squares is higher than the data labeled “With Diverter” and being illustrated with diamonds. These data indicate that the diverter and the flow restriction bar are effective at cooling the target during the heating.

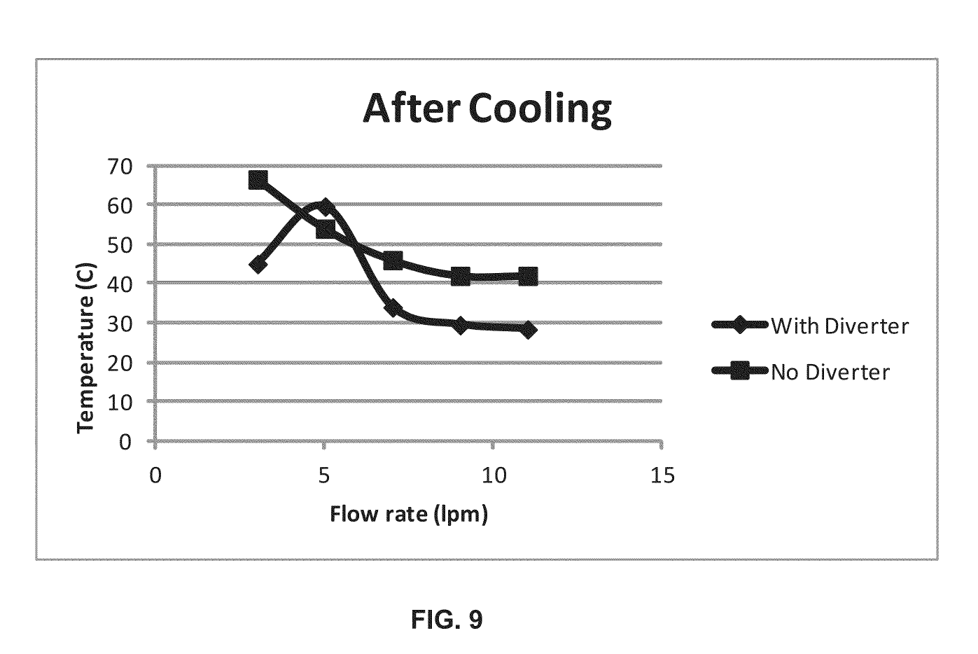

FIG. 9 presents data for temperature versus cooling water flow rate according to some embodiments. The magnetron and the fluid diverter were rotated at about 60 rpm. To simulate the target heating, a map gas torch was held at a distance of 2 inches from the target surface. The temperature of the map gas torch was about 2500C. The torch was allowed to heat the target surface for a period of 60 seconds and the temperature of the interface of the target to backing plate was measured with a thermocouple (TC) attached to the interface of the target to backing plate at the end of the 60 seconds. This configuration mimics the heating of the sputter gun assembly during the operation of the sputter gun. Cooling fluid (i.e. water) with a flow rate between 3 liter per minute (lpm) and 11 lpm was passed through the sputter gun assembly. The temperature was measured again, 30 seconds after the propane torch was turned off. FIG. 9 presents the data for the temperature of the interface of the target to backing plate at the end of the 30 second cooling period as a function of cooling fluid flow rate. The data labeled “No Diverter” and being illustrated with squares is higher than the data labeled “With Diverter” and being illustrated with diamonds, (except for the anomalous data point at 5 lpm for the “With Diverter” data set). These data indicate that the diverter and the flow restriction bar are effective at cooling the target after the heating step is complete.

The increased effectiveness of the cooling when employing the diverter and the flow restriction bar allows the use of higher power in the sputter gun assembly. The higher power results in faster deposition rates for the materials and leads to higher throughput and lower cost of ownership. The sputter guns described with reference to FIGS. 6 and 7 can be employed as part of an HPC PVD chamber which may further be employed as part of an HPC deposition system.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A sputter gun comprising:
a target affixed to a backing plate;
a magnetron disposed proximate to a surface of the backing plate opposite the target; and
a fluid diverter positioned around the magnetron, wherein slots formed within the fluid diverter are operable to direct a cooling fluid through a gap formed between the magnetron and the backing plate.

2. The sputter gun of claim 1 wherein the slots formed within the fluid diverter are on a face of the fluid diverter that is proximate to the backing plate.

3. The sputter gun of claim 1 wherein the magnetron can be moved to adjust a size of the gap formed between the magnetron and the backing plate.

4. The sputter gun of claim 1 further comprising a cooling chamber, the cooling chamber having a fluid inlet and a fluid outlet.

5. The sputter gun of claim 4 further comprising a flow restriction bar positioned within the cooling chamber so that cooling fluid is prevented from traversing from the fluid inlet to the fluid outlet unless it traverses the gap formed between the magnetron and the backing plate.

6. The sputter gun of claim 1 wherein each slot formed within the fluid diverter comprises a sharp edge and a beveled edge.

7. The sputter gun of claim 6 wherein the magnetron and the fluid diverter are rotated in a direction such that the beveled edge serves to force cooling fluid through the slot.

8. A method of cooling a sputter gun, the method comprising:
providing a cooling chamber, the cooling the chamber comprising a fluid inlet and a fluid outlet;
positioning a magnetron within the cooling chamber;
positioning a fluid diverter around the magnetron, the fluid diverter comprising slots operable to direct a cooling fluid through a gap formed between the magnetron and the backing plate;
introducing cooling fluid to the cooling chamber through the fluid inlet; and
rotating the magnetron and the fluid diverter, thereby forcing the cooling fluid through the gap formed between the magnetron and the backing plate.

9. The method of claim 8 further comprising positioning a flow restriction bar positioned within the cooling chamber so that the cooling fluid is prevented from traversing from the fluid inlet to the fluid outlet unless it traverses the gap formed between the magnetron and the backing plate.

10. The method of claim 8 wherein the slots formed within the fluid diverter are on a face of the fluid diverter that is proximate to the backing plate.

11. The method of claim 8 further comprising moving the magnetron to adjust a size of the gap formed between the magnetron and the backing plate.

12. The method of claim 8 wherein each of the slots in the fluid diverter further comprises a sharp edge and a beveled edge.

13. The method of claim 12 wherein the magnetron and the fluid diverter are rotated in a direction such that the beveled edge serves to force cooling fluid through the slot.
